(19) United States
(12) Patent Application Publication
(10) Pub. No.: US 2023/0094245 A1
(43) Pub. Date: Mar. 30, 2023

(54) MANUFACTURING METHOD OF ITO THIN FILM BASED ON SOLUTION METHOD

(71) Applicant: Wuhan China Star Optoelectronics Semiconductor Display Technology Co., Ltd., Wuhan, Hubei (CN)

(72) Inventors: Jia LI, Wuhan, Hubei (CN); Minli TAN, Wuhan, Hubei (CN)

(73) Assignee: Wuhan China Star Optoelectronics Semiconductor Display Technology Co., Ltd., Wuhan, Hubei (CN)

(21) Appl. No.: 16/971,325

(22) PCT Filed: Jun. 17, 2020
(86) PCT No.: PCT/CN2020/096595

§ 371 Date: Aug. 20, 2020

(30) Foreign Application Priority Data
Apr. 15, 2020 (CN) 202010296329.2

(51) Int. Cl. B05D 5/12; H01L 21/02; H01L 33/44; B05D 1/00; B05D 3/02; B05D 3/04; B05D 3/10

(52) U.S. Cl. CPC B05D 5/12; H01L 21/02112; H01L 21/02205; H01L 21/02521; H01L 21/02612; H01L 21/02697; H01L 33/44; B05D 1/005; B05D 3/02; B05D 3/0486; B05D 3/108; B05D 2601/20; B05D 2602/00; B05D 2401/40

(57) ABSTRACT

A manufacturing method of an indium tin oxide (ITO) thin film based on a solution method is disclosed. The manufacturing method includes: a step of providing an array substrate; a step of obtaining a dispersion solution by mixing ITO grains, an organic small molecule phase transfer agent, and an N-chlorosuccinimide (NCs) solution; a step of obtaining uniformly assembled ITO grains by coating the dispersion solution onto a passivation layer and baking to remove the organic small molecule phase transfer agent; and a step of obtaining the ITO thin film by annealing at an inert atmosphere to refine the ITO grains.

### CROSS REFERENCE TO RELATED APPLICATIONS

The present application claims priority of the Chinese patent application No. CN202010296329.2 filed on Apr. 15, 2020 with the National Intellectual Property Administration, titled “Manufacturing method of ITO thin film based on solution method”, which is incorporated by reference in the present application in its entirety.

### FIELD OF INVENTION

The present disclosure relates to the field of thin film preparation technologies, and more particularly, to a manufacturing method of an ITO thin film based on a solution method.

### BACKGROUND OF INVENTION

Since indium tin oxide (ITO) has features of low resistivity, a high transmittance in a visible range, and a greater optical band gap, it is widely used in fields of tablet displays and organic light-emitting diodes.

At present, ITO is generally obtained by magnetron sputtering film formation. However, techniques of sputtering have following disadvantages: a utilization rate of target materials is low, generally less than 40%, and poor adaptability to flexible substrates.

Therefore, it is necessary to provide a manufacturing method of an ITO thin film based on a solution method.

Technical problem: an embodiment of the present disclosure provides a manufacturing method of an ITO thin film based on a solution method by mixing ITO grains, tetrabutylammonium hydroxide, and an N-chlorosuccinimide (NCs) solution to obtain a dispersion solution, coating the dispersion solution and baking to remove tetrabutylammonium hydroxide to obtain uniformly assembled ITO grains, and annealing at an inert atmosphere to refine the ITO grains to obtain an ITO thin film. The ITO thin film has advantages of uniform structure, an ability to release stresses, and improved extensibility and flexibility of materials.

### SUMMARY OF INVENTION

At a first aspect, an embodiment of the present disclosure provides a manufacturing method of an indium tin oxide (ITO) thin film based on a solution method, comprising steps of:

a step of providing an array substrate and forming an opening on a passivation layer of the array substrate;

a step of obtaining a dispersion solution by mixing ITO grains, an organic small molecule phase transfer agent, and an N-chlorosuccinimide (NCs) solution, wherein the organic small molecule phase transfer agent is tetrabutylammonium hydroxide having a boiling point ranging from 85° C. to 115° C., and the NCs solution is a mixed solution of NCs dissolved in methanol;

a step of obtaining uniformly assembled ITO grains by coating the dispersion solution onto the passivation layer and baking at a temperature ranging from 90° C. to 130° C. to remove the organic small molecule phase transfer agent; and

a step of obtaining the ITO thin film by annealing at a temperature ranging from 280° C. to 320° C. at an inert atmosphere to refine the ITO grains.

In the manufacturing method, in the step of obtaining the uniformly assembled ITO grains, a coating method is at least one selected from spin coating and blade coating.

In the manufacturing method, in the step of obtaining the uniformly assembled ITO grains, a baking time ranges from 2 minutes to 7 minutes.

In the manufacturing method, in the step of obtaining the ITO thin film, an annealing time is greater than or equal to 1 hour.

In the manufacturing method, in the step of obtaining the ITO thin film, the inert atmosphere is a mixed gas of argon and helium, and a concentration ratio of helium to the inert atmosphere is 5%.

In the manufacturing method, in the step of obtaining the uniformly assembled ITO grains, an assembled thickness of the ITO grains ranges from 100Å to 1500Å.

At a second aspect, an embodiment of the present disclosure further provides a manufacturing method of an indium tin oxide (ITO) thin film based on a solution method, comprising steps of:

a step of providing an array substrate and forming an opening on a passivation layer of the array substrate;

a step of obtaining a dispersion solution by mixing ITO grains, an organic small molecule phase transfer agent, and an N-chlorosuccinimide (NCs) solution, wherein the organic small molecule phase transfer agent has a boiling point ranging from 85° C. to 115° C.;

a step of obtaining uniformly assembled ITO grains by coating the dispersion solution onto the passivation layer and baking to remove the organic small molecule phase transfer agent; and

a step of obtaining the ITO thin film by annealing at an inert atmosphere to refine the ITO grains.

In the manufacturing method, in the step of obtaining the dispersion solution, the organic small molecule phase transfer agent is tetrabutylammonium hydroxide.

In the manufacturing method, in the step of obtaining the dispersion solution, the NCs solution is a mixed solution of NCs dissolved in methanol.

In the manufacturing method, in the step of obtaining the uniformly assembled ITO grains, a coating method is at least one selected from spin coating and blade coating.

In the manufacturing method, in the step of obtaining the uniformly assembled ITO grains, a baking temperature ranges from 90° C. to 130 ° C., and a baking time ranges from 2 minutes to 7 minutes.

In the manufacturing method, in the step of obtaining the ITO thin film, an annealing temperature ranges from 280° C. to 320° C., and an annealing time is greater than or equal to 1 hour.

In the manufacturing method, in the step of obtaining the ITO thin film, the inert atmosphere is a mixed gas of argon and helium, and a concentration ratio of helium to the inert atmosphere is 5%.

In the manufacturing method, in the step of forming the opening on the passivation layer of the array substrate, the opening is etched to form by using a conventional 4-mask photolithography process.

In the manufacturing method, in the steps of obtaining the dispersion solution and obtaining the uniformly assembled ITO grains, an assembled thickness of the ITO grains is controlled by a concentration of the dispersion solution.

In the manufacturing method, in the step of obtaining the uniformly assembled ITO grains, an assembled thickness of the ITO grains ranges from 100Å to 1500Å.

Beneficial effect: compared to current technology, the manufacturing method of the ITO thin film based on the solution method provided by the present disclosure includes: a step of obtaining a dispersion solution by mixing ITO grains, an organic small molecule phase transfer agent, and an N-chlorosuccinimide (NCs) solution, wherein the organic small molecule phase transfer agent is tetrabutylammonium hydroxide; a step of obtaining uniformly assembled ITO grains by coating the dispersion solution onto the passivation layer and baking to effectively remove tetrabutylammonium hydroxide and controlling an assembled thickness of the uniformly assembled ITO grains by a concentration of the dispersion solution; and a step of obtaining an ITO thin film by annealing at an inert atmosphere to refine the ITO grains. The ITO thin film manufactured by the method in the embodiment of the present disclosure has advantages of uniform structure, an ability to release stresses, and improved extensibility and flexibility of materials. And the embodiment of the present disclosure etches to form an opening by a conventional 4-mask photolithography process, which can reduce a process cycle time of the array substrate and costs. In addition, equipments required in the present disclosure are simple and can be obtained using factory line equipments, and material utilization rates are high, so the present disclosure is expected to become a promising new solution for manufacturing ITO thin films on flexible substrates.

### DESCRIPTION OF DRAWINGS

FIG. 1 is a schematic structural diagram of an ITO thin film according to an embodiment of the present disclosure.

FIG. 2 is a flowchart of a manufacturing method of an ITO thin film based on a solution method according to an embodiment of the present disclosure.

FIG. 3 is a schematic state change diagram of ITO grains according to an embodiment of the present disclosure.

### DETAILED DESCRIPTION OF PREFERRED EMBODIMENTS

The present disclosure provides a manufacturing method of an ITO thin film based on a solution method. In order to make the purpose, technical solutions, and effects of the present disclosure more clear and definite, the following further describes the present disclosure in detail with reference to the drawings and embodiments. It should be understood that the specific embodiments described herein are only used to explain the disclosure, and are not used to limit the disclosure.

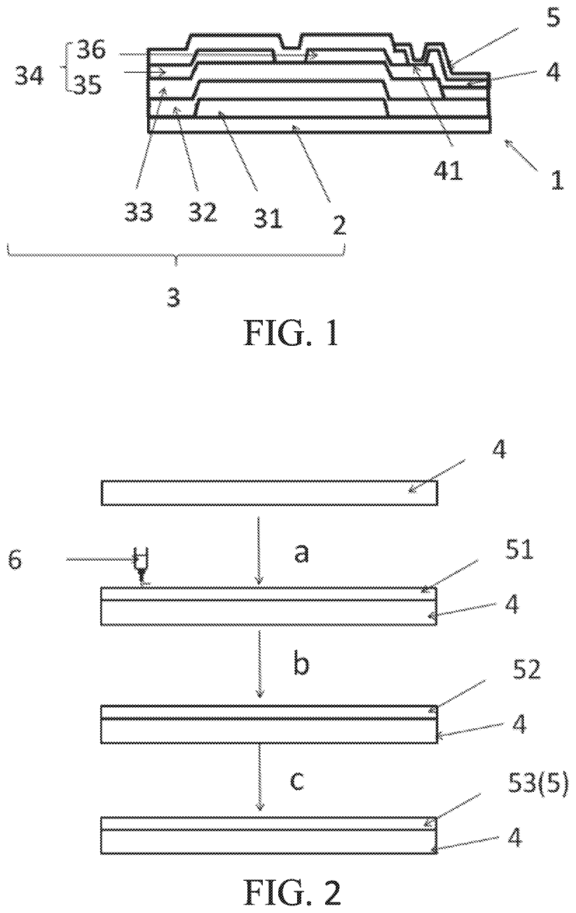

Referring to FIGS. 1 to 3, a manufacturing method of an ITO thin film based on a solution method provided by the present disclosure includes following steps:

(1) A step of providing an array substrate 1 and forming an opening 41 on a passivation layer 4 of the array substrate 1.

In the step, as shown in FIG. 1, the provided array substrate 1 includes a flexible substrate 2, a thin film transistor 3 disposed on the flexible substrate 2, and the passivation layer 4 disposed on the thin film transistor 3 and covering the thin film transistor 3. Wherein, the passivation layer 4 is provided with the opening 41 which is etched to form on the passivation layer 4 by a conventional 4-mask photolithography process.

Wherein, the thin film transistor 3 includes a gate electrode 31 disposed on the flexible substrate 2, a gate insulating layer 32 disposed on the gate electrode 31 and covering the gate electrode 31 and the flexible substrate 2, an active layer 33 disposed on the gate insulating layer 32, and a source/drain electrode 34 disposed on the active layer 33. The source/drain electrode 34 includes a source electrode 35 and a drain electrode 36, the passivation layer 4 is disposed on the source/drain electrode 34 and covers the source/drain electrode 34 and the gate insulating layer 32, and the passivation layer 4 is provided with the opening 41 which penetrates through the passivation layer 4 and extends to the drain electrode 36, wherein the opening 41 is used in a wiring layout in subsequent steps. Wherein, materials of the gate insulating layer 32 and the passivation layer 4 may be selected from SiNx.

(2) A step of obtaining a dispersion solution by mixing ITO grains, an organic small molecule phase transfer agent, and an N-chlorosuccinimide (NCs) solution, wherein the organic small molecule phase transfer agent has a boiling point ranging from 85° C. to 115° C.

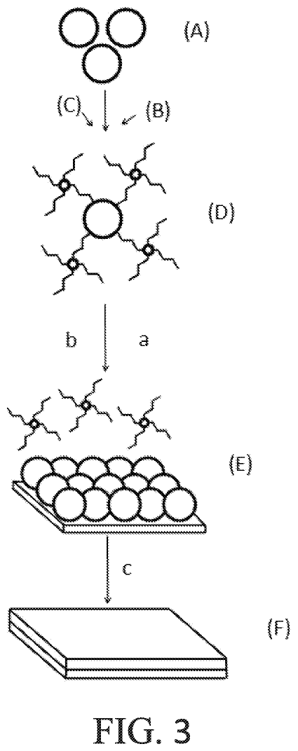

In the step, as shown in FIG. 3, the ITO grains A as a solute have characteristics of a boiling point being 82° C., a melting point being 287° C., and insolubility in water. The NCs solution C is a mixed solution of NCs dissolved in methanol and has chemical characteristics of a boiling point being 216.5° C., solubility in water, alcohol, benzene, acetone, and acetic acid, and slight solubility in ether, chloroform, carbon tetrachloride, and petroleum ether. The organic small molecule phase transfer agent B is used as a dispersant, and without affecting the chemical characteristics of the ITO grains A, the boiling point of the organic small molecule phase transfer agent B ranges from 85° C. to 115° C.

In the embodiment, the organic small molecule phase transfer agent

B is selected from tetrabutylammonium hydroxide (TBAOH), a chemical formula of tetrabutylammonium hydroxide is (C₄H₉)₄NOH, which has a molecular weight of 259.47 and a boiling point of 100° C., and tetrabutylammonium hydroxide is an organic strong base, having characteristics of solubility in water and methanol, and a structural formula of tetrabutylammonium hydroxide is:

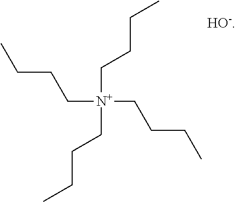 [SMILES: CCCC[N+](CCCC)(CCCC)CCCC ; "HO-."]

A chemical substance information of tetrabutylammonium hydroxide in the Environmental Protection Agency (EPA) is 1-Butanaminium, N,N,N-tributyl-, hydroxide (2052-49-5).

It is worth mentioning that a document (Applied Physics Letters.2007, 91(15), 3588 ; Langmuir.2004, 20, 6946) demonstrates that tetrabutylammonium hydroxide can replace a long-chain phase transfer agent as a dispersant to effectively disperse metal oxide, thereby obtaining a uniform metal oxide dispersion solution. Therefore, tetrabutylammonium hydroxide can effectively disperse the ITO grains A into the NCs solution C, thereby obtaining the dispersion solution D.

In other embodiments, the organic small molecule phase transfer agent B may be selected from other common substances known by the skilled in the art as the dispersant, which is not specifically limited herein.

(3) A step of obtaining uniformly assembled ITO grains E by coating the dispersion solution D onto the passivation layer 4 and baking to remove the organic small molecule phase transfer agent B.

In the step, as shown in FIG. 1 and the step a of FIG. 2, using a coating method, the dispersion solution D is uniformly coated on the passivation layer 4 by a coater 6. Specifically, the dispersion solution D is uniformly coated on a surface of the passivation layer 4 facing away from one side of the drain electrode 36, and the dispersion solution D is accommodated in the opening 41 and is coated on a surface of the opening 41 corresponding to the drain electrode 36. In the step, after coating on the passivation layer 4, the dispersion solution D forms a coating layer 51, and the coating method is at least one selected from spin coating and blade coating, and is not limited to the above coating methods.

In the step, as shown in the step b of FIG. 2, the coating layer 51 is baked, a baking temperature ranges from 90° C. to 130° C., and a baking time ranges from 2 minutes to 7 minutes, thereby effectively removing the organic small molecule phase transfer agent B and forming a baked layer 52 shown in FIG. 2 to obtain the uniformly assembled ITO grains E shown in FIG. 3. In a specific embodiment, the baking temperature and the baking time can be set according to a specific coating situation in the step a of FIG. 2. For example, in a specific embodiment, when the organic small molecule phase transfer agent B selects tetrabutylammonium hydroxide as the dispersant and when the baking temperature in the step is set to be 120° C. and the baking time is set to be 5 minutes, tetrabutylammonium hydroxide can be removed and the ITO grains E can be arranged uniformly, thereby the ITO grains E having higher quality.

In other embodiments, in the steps of obtaining the dispersion solution and obtaining the uniformly assembled ITO grains, the skilled in the art can also change a concentration of the dispersion solution D to control an assembled thickness of the ITO grains E, and the assembled thickness of the ITO grains ranges from 100Å to 1500Å.

(4) A step of obtaining an ITO thin film by annealing at an inert atmosphere to refine the ITO grains.

In the step, as shown in the step c of FIG. 2, the uniformly assembled ITO grains E is refined by annealing at the inert atmosphere to obtain refined ITO grains F in FIG. 3, and the ITO thin film 53 shown in FIG. 2 includes the refined ITO grains F. Wherein, In the embodiment of the present disclosure, as a preferred embodiment, an annealing temperature ranges from 280° C. to 320° C., and an annealing time is greater than or equal to 1 hour. In addition, as a preferred embodiment, the inert atmosphere is a mixed gas of argon and helium, and a concentration ratio of helium to the inert atmosphere is 5%. In a specific embodiment, the annealing temperature and the inert atmosphere can be selected according to the specific coating situation in the step (3). For example, in a specific embodiment, the annealing temperature is 300° C., and the annealing time is 1 hour. the obtained refined ITO grains F after annealing have advantages of uniform structure, an ability to release stresses, and improved extensibility and flexibility of materials.

The specific implementation of the above operations can be referred to the previous embodiments, and will not be repeated here.

In summary, the manufacturing method provided by the present disclosure includes: the step of obtaining the dispersion solution D by mixing the ITO grains A, the organic small molecule phase transfer agent B, and the NCs solution C, wherein the organic small molecule phase transfer agent B is tetrabutylammonium hydroxide; the step of obtaining the uniformly assembled ITO grains E by coating the dispersion solution D onto the passivation layer 4 of the array substrate 1 and baking to effectively remove the organic small molecule phase transfer agent, that is tetrabutylammonium hydroxide, wherein, the assembled thickness of the uniformly assembled ITO grains E can be controlled by adjusting the concentration of the dispersion solution D; and the step of obtaining the ITO thin film 53 by annealing at the inert atmosphere to obtain the refined ITO grains F. The ITO thin film manufactured by the method in the embodiment of the present disclosure has advantages of uniform structure, an ability to release stresses, and improved extensibility and flexibility of materials. In the step of forming the opening 41 on a planarization layer 4 of the array substrate 1, the embodiment of the present disclosure etches to form the opening 41 by the conventional 4-mask photolithography process, which can reduce a process cycle time of the array substrate and costs. In addition, equipments required in the present disclosure are simple and can be obtained using factory line equipments, and material utilization rates are high, so the present disclosure is expected to become a promising new solution for manufacturing ITO thin films on flexible substrates.

It can be understood that for a person of ordinary skill in the art, equivalent replacements or changes can be made according to the technical solution of the present disclosure and its inventive concept, and all these changes or replacements should fall within the protection scope of the claims attached to the present disclosure.

What is claimed is:

1. A manufacturing method of an indium tin oxide (ITO) thin film based on a solution method, comprising steps of:
a step of providing an array substrate and forming an opening on a passivation layer of the array substrate;
a step of obtaining a dispersion solution by mixing ITO grains, an organic small molecule phase transfer agent, and an N-chlorosuccinimide (NCs) solution, wherein the organic small molecule phase transfer agent is tetrabutylammonium hydroxide having a boiling point ranging from 85° C. to 115° C., and the NCs solution is a mixed solution of NCs dissolved in methanol;
a step of obtaining uniformly assembled ITO grains by coating the dispersion solution onto the passivation layer and baking at a temperature ranging from 90° C. to 130° C. to remove the organic small molecule phase transfer agent; and
a step of obtaining the ITO thin film by annealing at a temperature ranging from 280° C. to 320° C. at an inert atmosphere to refine the ITO grains.

2. The manufacturing method according to claim 1, wherein in the step of obtaining the uniformly assembled ITO grains, a coating method is at least one selected from spin coating and blade coating.

3. The manufacturing method according to claim 2, wherein in the step of obtaining the uniformly assembled ITO grains, a baking time ranges from 2 minutes to 7 minutes.

4. The manufacturing method according to claim 1, wherein in the step of obtaining the ITO thin film, an annealing time is greater than or equal to 1 hour.

5. The manufacturing method according to claim 1, wherein in the step of obtaining the ITO thin film, the inert atmosphere is a mixed gas of argon and helium, and a concentration ratio of helium to the inert atmosphere is 5%.

6. The manufacturing method according to claim 1, wherein in the step of obtaining the uniformly assembled ITO grains, an assembled thickness of the ITO grains ranges from 100Å to 1500Å.

7. A manufacturing method of an indium tin oxide (ITO) thin film based on a solution method, comprising steps of:
a step of providing an array substrate and forming an opening on a passivation layer of the array substrate;
a step of obtaining a dispersion solution by mixing ITO grains, an organic small molecule phase transfer agent, and an N-chlorosuccinimide (NCs) solution, wherein the organic small molecule phase transfer agent has a boiling point ranging from 85° C. to 115° C.;
a step of obtaining uniformly assembled ITO grains by coating the dispersion solution onto the passivation layer and baking to remove the organic small molecule phase transfer agent; and
a step of obtaining the ITO thin film by annealing at an inert atmosphere to refine the ITO grains.

8. The manufacturing method according to claim 7, wherein in the step of obtaining the dispersion solution, the organic small molecule phase transfer agent is tetrabutylammonium hydroxide.

9. The manufacturing method according to claim 7, wherein in the step of obtaining the dispersion solution, the NCs solution is a mixed solution of NCs dissolved in methanol.

10. The manufacturing method according to claim 7, wherein in the step of obtaining the uniformly assembled ITO grains, a coating method is at least one selected from spin coating and blade coating.

11. The manufacturing method according to claim 10, wherein in the step of obtaining the uniformly assembled ITO grains, a baking temperature ranges from 90° C. to 130° C., and a baking time ranges from 2 minutes to 7 minutes.

12. The manufacturing method according to claim 7, wherein in the step of obtaining the ITO thin film, an annealing temperature ranges from 280° C. to 320° C., and an annealing time is greater than or equal to 1 hour.

13. The manufacturing method according to claim 12, wherein in the step of obtaining the ITO thin film, the inert atmosphere is a mixed gas of argon and helium, and a concentration ratio of helium to the inert atmosphere is 5%.

14. The manufacturing method according to claim 7, wherein in the step of forming the opening on the passivation layer of the array substrate, the opening is etched to form by using a conventional 4-mask photolithography process.

15. The manufacturing method according to claim 7, wherein in the steps of obtaining the dispersion solution and obtaining the uniformly assembled ITO grains, an assembled thickness of the ITO grains is controlled by a concentration of the dispersion solution.

16. The manufacturing method according to claim 15, wherein in the step of obtaining the uniformly assembled ITO grains, the assembled thickness of the ITO grains ranges from 100Å to 1500Å.
